(19) United States
(12) Patent Application Publication
(10) Pub. No.: US 2013/0277753 A1
(43) Pub. Date: Oct. 24, 2013

(54) BICMOS DEVICES ON ETSOI

(71) Applicants: William F. Clark, JR., Essex Junction, VT (US); Qizhi Liu, Essex Junction, VT (US); Robert Mark Rassel, Essex Junction, VT (US); Yun Shi, Essex Junction, VT (US)

(72) Inventors: William F. Clark, JR., Essex Junction, VT (US); Qizhi Liu, Essex Junction, VT (US); Robert Mark Rassel, Essex Junction, VT (US); Yun Shi, Essex Junction, VT (US)

(73) Assignee: INTERNATIONAL BUSINESS MACHINES CORPORATION, ARMONK, NY (US)

(21) Appl. No.: 13/451,806

(22) Filed: Apr. 20, 2012

(51) Int. Cl. H01L 27/088; G06F 17/50; H01L 21/8249

(52) U.S. Cl. 257/378; 438/234; 716/100; 257/E27.074; 257/E21.696

(57) ABSTRACT

A BiCMOS device structure, method of manufacturing the same and design structure thereof are provided. The BiCMOS device structure includes a substrate having a layer of semiconductor material upon an insulating layer. The BiCMOS device structure further includes a bipolar junction transistor structure formed in a first region of the substrate having an extrinsic base layer formed at least partially from a portion of the layer of semiconductor material.

### BACKGROUND

### Field of the Invention

The present invention relates to BiCMOS devices, and more particularly, to BiCMOS devices formed on an Extremely Thin Semiconductor-on-Insulator (“ETSOI”) layer, method of manufacturing the same and design structure thereof.

Transistors are multi-electrode semiconductor devices in which the current flowing between two specified electrodes is controlled or modulated by the voltage applied at a third (control) electrode. Transistors fall into two major classes: field-effect transistors (FETs), and bipolar junction transistors (BJTs).

FETs include a source, a drain, and a gate. A voltage applied to the gate results in a current flow between the source and the drain of the FET through a channel that is formed beneath the gate. A commonly used FET is a complimentary metal oxide semiconductor transistor, or CMOS transistor. CMOS transistors can be either NMOS or PMOS transistors, depending upon the type of semiconductor materials used to form the transistor. CMOS semiconductors typically include both NMOS and PMOS transistors in one semiconductor.

There are known methods of forming FET devices on a semiconductor-on-insulator (SOI) substrate having an Extremely Thin Semiconductor-on-Insulator (“ETSOI”) layer. An ETSOI layer is the semiconductor layer that is present upon the buried insulating layer of an SOI substrate. In accordance with these known methods, FET gate stack is formed on the upper surface of ETSOI layer. CMOS transistors produced on ETSOI layer generally achieve lower junction capacitances and higher operational speeds.

BJTs comprise two p-n junctions placed back-to-back in close proximity to each other, with one of the regions common to both junctions. This forms either a p-n-p or an n-p-n transistor depending upon the characteristics of the semiconductor materials used. A BJT is a three-terminal device that can controllably vary the magnitude of the current that flows between two of the terminals. The three terminals include a base terminal, a collector terminal, and an emitter terminal. The movement of electrical charge carriers that produce electrical current flow between the collector and the emitter terminals vary dependent upon variations in the voltage on the base terminal thereby causing the magnitude of the current to vary. Thus, the current flow through the emitter and collector electrodes is controlled by the voltage across the base-emitter junction. HBTs are BJTs where the emitter-base junction is a heterojunction between semiconductor materials of different, but similarly functioning types. Recently, demand for HBTs has increased significantly because these transistors are capable of operating at higher speeds and driving more current. These characteristics are important for high-speed, high frequency communication networks such as those required by cell phones and computers.

BJTs can be used to provide linear voltage and current amplification because small variations of the base-emitter voltage and hence the base current at the input terminal result in large variations of the output collector current. The transistor can also be used as a switch in digital logic and power switching applications, switching from an “off” state to an “on” state. Such BJTs find application in analog and digital circuits and integrated circuits, at all frequencies from audio to radio frequency.

BiCMOS semiconductors include BJTs and CMOS transistors manufactured in the same semiconductor. Accordingly, it is desirable to provide a structure and method of forming BICMOS devices on an ETSOI layer.

### SUMMARY

In an aspect of the invention, a semiconductor device structure comprises a substrate having a layer of semiconductor material upon an insulating layer. The semiconductor device structure further comprises a bipolar junction transistor structure formed in a first region of the substrate having an extrinsic base layer formed at least partially from a portion of the layer of semiconductor material.

In another aspect of the invention, a method for fabricating a semiconductor device structure comprises providing a substrate having a layer of semiconductor material that is formed on an insulating layer. The method further comprises forming a bipolar junction transistor structure in a first region of the substrate. The bipolar junction transistor structure comprises an extrinsic base layer that is formed at least partially from a portion of the layer of semiconductor material.

In another aspect of the invention, a design structure embodied in a machine readable medium for designing, manufacturing, or testing an integrated circuit is provided. The design structure comprises the structures and/or methods of the present invention.

A more complete understanding of the present invention, as well as further features and advantages of the present invention, will be obtained by reference to the following detailed description and drawings. It is to be understood that both the foregoing general description and the following detailed description are exemplary and explanatory only, and should not be considered restrictive of the scope of the invention, as described and claimed. Further, features or variations may be provided in addition to those set forth herein. For example, embodiments of the invention may be directed to various combinations and sub-combinations of the features described in the detailed description.

### BRIEF DESCRIPTION OF THE SEVERAL VIEWS OF THE DRAWINGS

The present invention is described in the detailed description which follows in reference to the noted plurality of drawings by way of non-limiting examples of exemplary embodiments of the present invention.

FIG. 1 is a cross-sectional view of conventionally formed ETSOI FET devices according to the prior art;

FIGS. 2 through 7 schematically illustrate method steps for fabrication of a BiCMOS semiconductor device structure in accordance with an embodiment of the present invention; and

FIG. 8 is a flow diagram of a design process used in semiconductor design, manufacture, and/or test.

### DETAILED DESCRIPTION

An embodiment of the present invention relates to a structure and method of forming BiCMOS devices. More specifically, an embodiment of the present invention comprises a semiconductor device structure which includes a substrate having a layer of semiconductor material upon an insulating layer. The semiconductor device structure further comprises a bipolar junction transistor structure present in a first region of the substrate having an extrinsic base layer advantageously formed at least partially from a portion of the layer of semiconductor material. Advantageously, the structure of disclosed embodiment of the present invention is an improvement over prior art as it eliminates one or more process steps of forming a raised extrinsic base layer, which is typically done by growing a semiconductor layer.

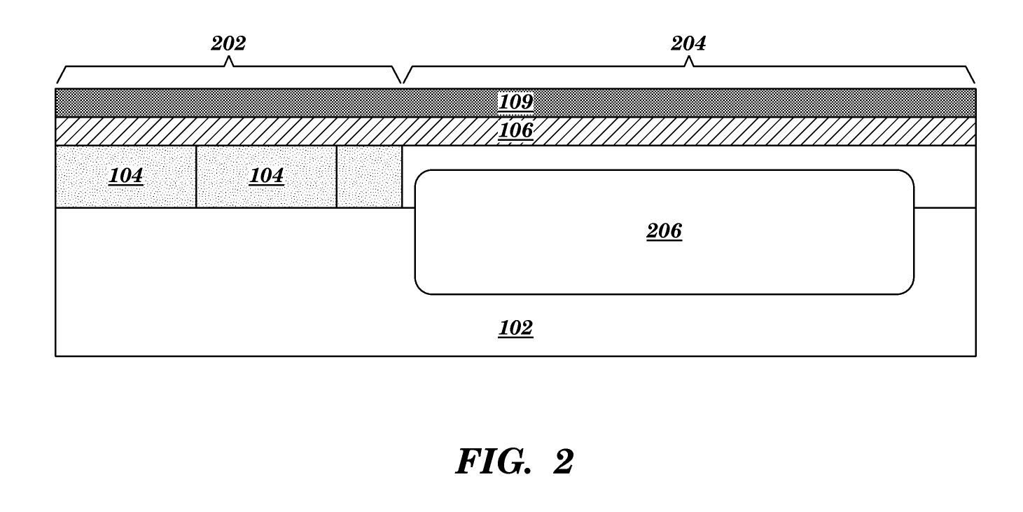

FIGS. 2 through 7 schematically illustrate method steps for fabrication of a BiCMOS semiconductor device structure in accordance with an embodiment of the present invention. For convenience, when the discussion of the fabrication steps of the present invention refers to a particular type of substrate and/or particular type of dopant impurities, it is understood that the present invention is applicable to the opposite type without departing from the spirit of the present invention. For instance, when reference is made to a p-type silicon substrate as the semiconductive substrate and n-type impurities as diffused or implanted dopant impurity, it is understood that an n-type substrate and p-type diffused or implanted dopant impurities are likewise suitable. In addition, it is understood that when the discussion refers to n-type impurities, the process steps are applicable to p-type impurities and vice versa. Also, when reference is made to impurities of a “first type” and to impurities of a “second type,” it is understood that the “first type” refers to an n-type or p-type impurities and “second type” refers to the opposite conductivity type. That is, if the “first type” is p, then the “second type” is n. If the “first type” is n, then the “second type” is p. However, once a convention is selected for manufacturing of a bipolar transistor, the convention must be maintained. That is, either all first type dopants must be N doped and all second type dopants P doped, or all first type dopants must be P doped and all second type dopants N doped.

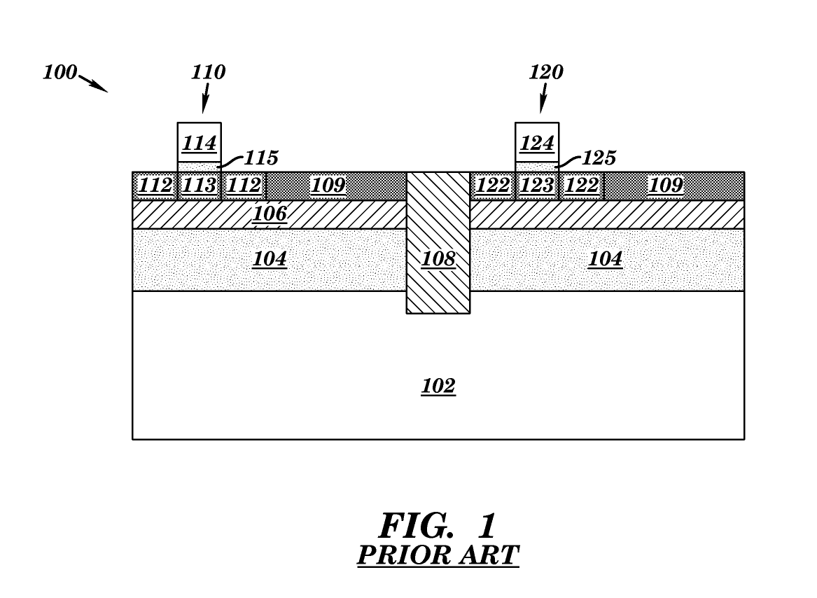

Referring initially to FIG. 1, there is shown a cross-sectional view of two conventionally formed ETSOI FET devices, such as NFET 110 and PFET 120 of complimentary metal oxide (CMOS) circuitry. Semiconductor substrate 102 may be any type of wafers of suitable semiconductor material. Preferably, the initial substrate is a single crystal silicon wafer. Semiconductor substrate 102 may be of a p-type lightly doped semiconductor substrate, as is well known in the art. As is shown a bulk substrate 102 has a buried insulator layer 106 (in this instance a buried oxide layer or BOX) formed thereon. BOX layer 106 may have a thickness from approximately 10 nm to approximately 200 nm. A thin silicon layer 109 is in turn formed over the BOX layer 106. The thin silicon layer 109 (hereafter referred to as ETSOI layer) may have a thickness from approximately 5 nm to approximately 100 nm, preferably from approximately 6 nm to approximately 8 nm, thereby forming an ETSOI substrate. Accordingly, the fully depleted ETSOI devices, such as NFET 110 and PFET 120 of FIG. 1 further include embedded source/drain regions 112 and 122, respectively, formed at least partially from a portion of ETSOI layer 109. One skilled in the art will recognize that carriers, such as electrons and holes, flow through the channel regions between the source regions and drain regions in a horizontal direction.

One skilled in the art will also recognize other conventional structures associated with FET devices. NFET 110 and PFET 120 are separated by shallow trench isolation (STI) region 108 (for example, an oxide material) for providing electrical isolation between individual transistors. NFET device 110 further comprises gate electrode 114 (for example, polysilicon or other suitable conducting material) disposed over a channel region 113 (for example, polysilicon or other suitable conducting material) and a gate dielectric layer 115 (for example, oxide, nitride, oxynitride, and the like) to electrically isolate gate electrode 114 from ETSOI layer 109. Similarly, PFET device 120 further comprises gate electrode 124 disposed over a channel region 123 and a gate dielectric layer 125 electrically isolating gate electrode 124 from ETSOI layer 109. In addition, NFET 110 and PFET 120 devices may include back-gates 104 situated in a top portion of substrate 102, below BOX layer 106, as illustrated in FIG. 1. As previously indicated, BiCMOS semiconductors include BJTs and CMOS transistors manufactured in the same semiconductor.

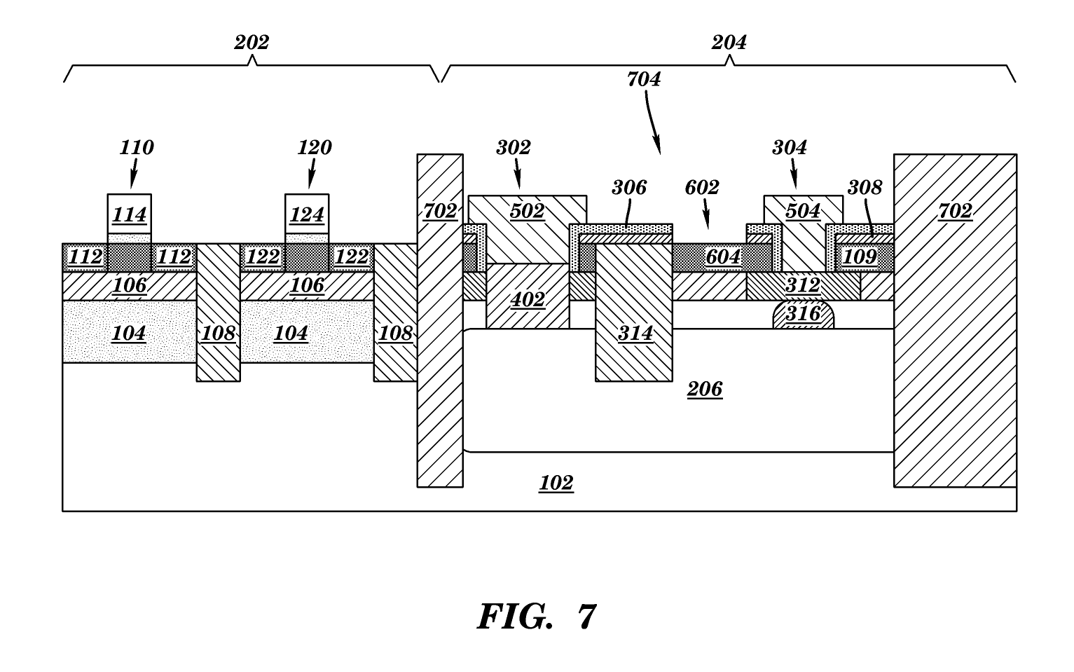

In the following sections, for the ease of description, structures of the semiconductor device illustrated in FIGS. 2 through 7 may be referred to as BJT in general, even though some of the drawings may only illustrate a part of BJT, or in other words, a work-in-progress BJT 704. A completed BJT 704 is demonstratively illustrated in FIG. 7.

FIGS. 2 through 7 schematically illustrate method steps for fabrication of a BiCMOS semiconductor device structure in accordance with an embodiment of the present invention. For clarity, both the CMOS device region 202 and BJT device region 204 are shown.

According to an embodiment, a process and/or method of fabrication may start with ETSOI substrate described above. BiCMOS semiconductor devices include BJTs and CMOS transistors manufactured in two adjacent regions on the same semiconductor substrate. For example, as shown in FIG. 2. BJTs may be fabricated in a first region 204 over the ETSOI substrate and CMOS transistors may be fabricated in a second region 202. Regions 202 and 204 are adjacent to each other.

The present embodiment of a method of fabrication may include forming a buried sub-collector region 206 in first region 204, as shown in FIG. 2. The buried sub-collector region 206 may be located within ETSOI substrate. Buried sub-collector region 206 may be formed utilizing implantation conditions that are capable of implanting n-type or p-type dopants into the semiconductor substrate 102, which may be followed by high temperature thermal anneal, such that the upper surface of the buried sub-collector 206 is close to the lower surface of BOX layer 106. The exact implant conditions for sub-collector formation may vary depending on the type of dopant employed. The implant conditions are well known and are within knowledge of one skilled in the art. In an embodiment, the buried sub-collector 206 is a n-type sub-collector which has been formed by ion implanting an n-type dopant such as arsenic into the ETSOI substrate using an ion dose from approximately 2×10¹⁹ to approximately 8×10²⁰ atoms/cm³ and an implant energy from approximately 40 keV to approximately 500 keV. The implant may be performed using a masked process.

Still referring to FIG. 2, after the buried sub-collector 206 is formed, the first region 204 may be protected with a patterned insulating layer (not shown). The patterned insulating layer, which may be, for example, a nitride such as Si₃N₄ overlying a silicon dioxide layer. The patterned insulating layer may be formed by deposition, lithography and etching. At this point of the embodiment of the present invention, one or more CMOS transistors such as FETs are formed in the second region 202. A mask may be formed over sections of ETSOI layer 109 in the second region 202 to form back gates. Specifically, a masked implantation process may be used to form in each section 104 either an NFET back gate or PFET back gate. More specifically, one section 104 may be masked. Then unmasked section 104 may be implanted with a first conductivity type dopant to form at least one doped back gate for at least one first conductivity type FET. Following the first implant, the mask over the first of the sections 104 may be removed and the second section 104 may be masked. A second implantation process implants the unmasked section 104 with a second conductivity type dopant to form at least one doped back gate for at least one second conductivity type FET.

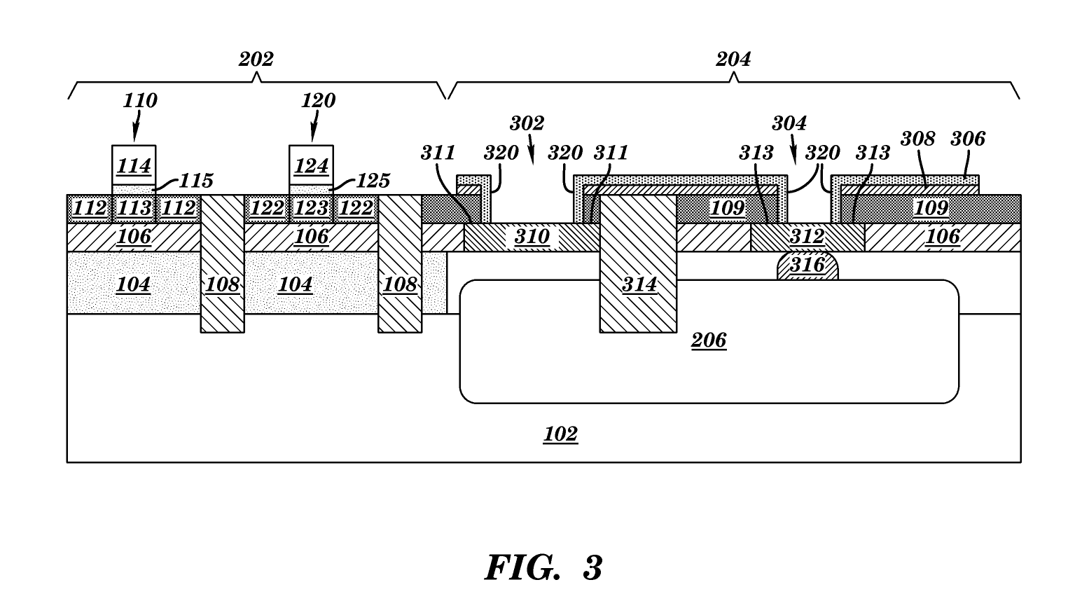

Referring to FIG. 3, once the back gates 104 are formed for the FETs, conventional CMOS processing may continue to form FETs in the second region 202. Specifically, shallow trench isolation (STI) structures 108 may be formed in the ETSOI substrate using conventional processes. After the STI 108 structures are formed, both n-type and p-type FETs can be formed above the n-doped and p-doped back gates 104, respectively, in order to form NFET 110 and PFET 120 devices. The FETs are formed first and then the BJTs are formed subsequently in the first region 204 adjacent to the second region 202, as shown in FIG. 3. The FETs may be formed by process methods well known in the art such as ion implantation to form source/drain regions 112 and 122 (for NFET 110 and PFET 120, respectively). Gates 114 and 124 may also be formed by process methods well known in the art such as deposition of one or more films, patterning gates 114 and 124 using photolithography and etching of gate films and gate dielectric 115 and 125 resulting in the NFET 110 and PFET 120 structures shown in FIG. 3 in the second region 202 of the ETSOI substrate. Following fabrication of the CMOS transistors, the CMOS transistor region (second region 202) is protected with a protective layer (not shown) that may protect FETs during the BJT construction in the first region 204. The protective layer may be an oxide formed by a conventional deposition process.

According to an embodiment, a fabrication of BJT may begin with the formation of isolation region 314. Isolation region 314, in an embodiment an oxide region, may be formed using STI process well known in the art of semiconductor processing. However, isolation region 314 may be formed using other methods and may be formed from any suitable type of dielectric material, such as nitrides. Isolation region 314 serves to isolate the base of the BJT from the collector region.

In an embodiment, first region 204 of the ETSOI substrate is thereupon conformally coated with an oxide layer 308, as shown in FIG. 3. Oxide layer 308 may have a thickness from approximately 20 nm to approximately 200 nm. Oxide layer 308 may be deposited using low pressure chemical vapor deposition (LPCVD) process, rapid chemical vapor deposition (RTCVD) process, or the like. Next a thick nitride layer 306 may be deposited on top of the oxide layer 308. Nitride layer 306 may have a thickness from approximately 20 nm to approximately 150 nm. Nitride layer 306 may be deposited using LPCVD process. In an embodiment, this nitride layer 306 may be etched using a particular anisotropic dry etching process, until in a known way a side-string or a so-called “spacer” 320 of silicon nitride remains. In this etching step not only the nitride layer 306 may be etched away but also the previously applied oxide layer 308, the ETSOI layer 109 and the BOX layer 106 in regions 302 and 304. The etching may be stopped, when the surface of the semiconductor substrate 102 has been exposed. The openings formed in this etching process will form the so called collector contact opening 302 and emitter opening 304. At the end of BJT fabrication process, subsequently formed collector contact region 502 and emitter 504 will be separated from the ETSOI layer 109 by the nitride spacers 320 in regions 302 and 304 and by the nitride layer 306 and oxide layer 308 at the top surface of ETOSI layer 109, as shown in FIG. 7.

FIG. 3 also shows formation of selectively implanted collector (SIC) region 316 in semiconductor substrate 102 underneath emitter opening 304. SIC region 316 is self-aligned by emitter opening 304 in which intrinsic base 312 and the emitter may be formed subsequently. SIC region 316 may be implanted through emitter opening 304 at high energies (typically, from approximately 40 KeV to approximately 100 KeV) to create a slightly concentrated (from approximately 5×10¹⁷ to approximately 5×10¹⁸ atoms/cm³) SIC region 316 coextensive with the intrinsic base and emitter to be formed within opening 304. SIC region 316 offers a low parasitic capacitance between the emitter and collector.

In an embodiment, an oxide wet etching may be performed to open regions 311 and 313, shown in FIG. 3, under the ETSOI layer 109. The BOX layer 106 in the collector and emitter windows, 302 and 304, respectively, may be exposed and removed so as to form free space for later SiGe/Si growth in direct contact with the polysilicon of ETSOI layer 109. The oxide undercuts 311 and 313 should be sufficient to permit a good link between intrinsic base 312 and layer 109 (advantageously used as an extrinsic base, as discussed herein). FIG. 3 illustrates that an intrinsic base layer 312 may be formed on a bottom surface of emitter opening 304. Intrinsic base layer 312 may be an epitaxial layer of semiconductor material, such as silicon (Si), and/or semiconductor compound alloy such as SiGe. Intrinsic base layer 312 may be selectively grown on the exposed silicon substrate 102 inside the emitter opening 304. The growth of the layer can occur with or without silicon nucleation. Intrinsic base layer 312 may have substantially the same layer thickness as BOX layer 106 from approximately 10 nm to approximately 200 nm, preferably from approximately 10 nm to approximately 20 nm, with concentration of Ge varying from approximately 5% to approximately 30%. Intrinsic base layer 312 may be intrinsically doped with a P-type dopant, such as, but not limited to, boron (B), with or without an addition of carbon (C). Intrinsic base layer 312 may be grown such that it covers at least a portion of top surface of SIC region 316. Intrinsic base layer 312 is in electrical contact with the SIC region 316. In an embodiment, this layer of SiGe material may also be grown in a region 310 by a selective epitaxial growth process on the exposed semiconductor substrate 102 at a bottom surface of collector opening 302. Layer 310 may have substantially the same layer thickness as BOX layer 106 and intrinsic base layer 312, as shown in FIG. 3.

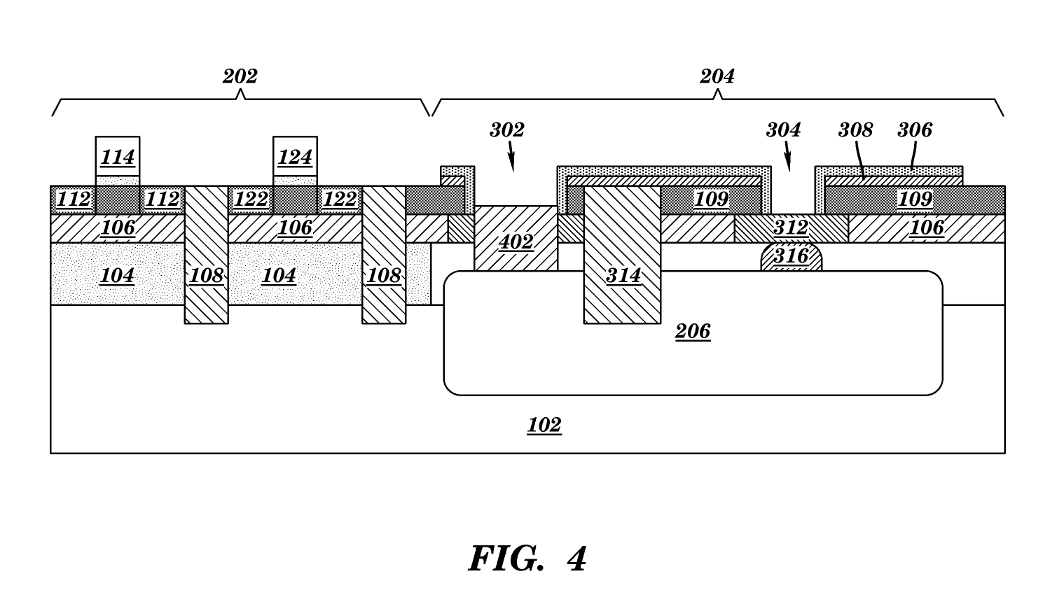

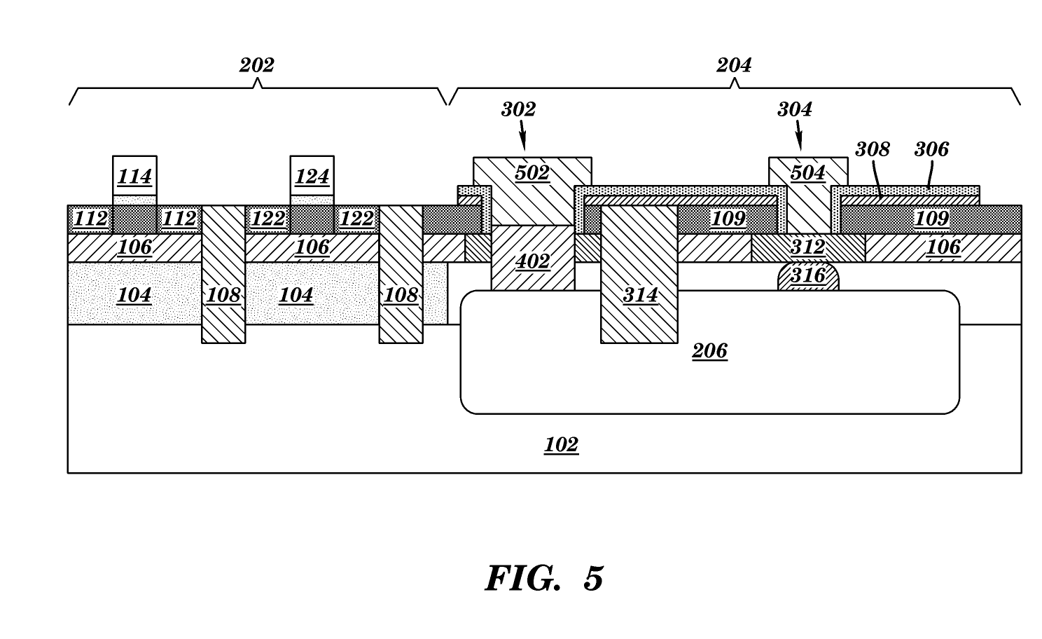

Turning now to FIG. 4, the formation of a reach through region 402 is illustrated. This may be done by selectively depositing a reach through implant resist (RN) (not shown), leaving openings in the collector opening 302 over the region 310. A reach through implant may then be performed using ion implantation technique with N-type impurity ions. The RN resist may then be stripped. The N-type implanted ions can be phosphorus ions, arsenic ions, antimony ions, and the like. In an embodiment the implantation energy ranges from approximately 40 keV to approximately 500 keV. The doping concentration may be within a range of approximately 1×10¹⁹ _atoms per cm³ to approximately 2×10²⁰ atoms per cm³. Substantially, part of this dosage of N-type ions can neutralize the effect of the p-type impurities implanted during the formation of region 310, and the other part may provide the sufficient carriers for desired N-type conductivity of the reach through region 402. Therefore, in this embodiment, selectively grown region 310 is converted from the P-type doped region into the N-type doped region 402. N-type reach through region 402 provides a vertical conductive pathway from subsequently formed N-type collector contact region 502 (shown in FIG. 5) to sub-collector region 206.

As shown in FIG. 5, a next step in an embodiment may include forming a collector contact region 502 in the collector opening 302 and forming an emitter 504 in the emitter opening 304 by a selective epitaxial growth process. According to an illustrative embodiment, collector contact region 502 and emitter 504 may be an epitaxial layer of semiconductor material, such as silicon (Si), or semiconductor compound alloy such as SiGe. Collector contact region 502 and emitter 504 may be formed with in-situ doping (n-type) material. In-situ doping refers to the doping technique wherein the dopants are introduced to the layers 502 and 504 at the same time epitaxial layers 502 and 504 are being grown. Collector contact region 502 may be formed to have a thickness of between approximately 0.05 microns and approximately 0.2 microns. Emitter 602 may be formed to have a thickness of between approximately 0.05 microns and approximately 0.2 microns. In the embodiment shown in FIG. 5 collector contact region 502 and emitter 504 are separated from ETSOI layer 109 by nitride layer 306 and oxide layer 308. According to the present embodiment, upper portions of collector contact region 502 and emitter 504 overlie the top surface of nitride layer 306.

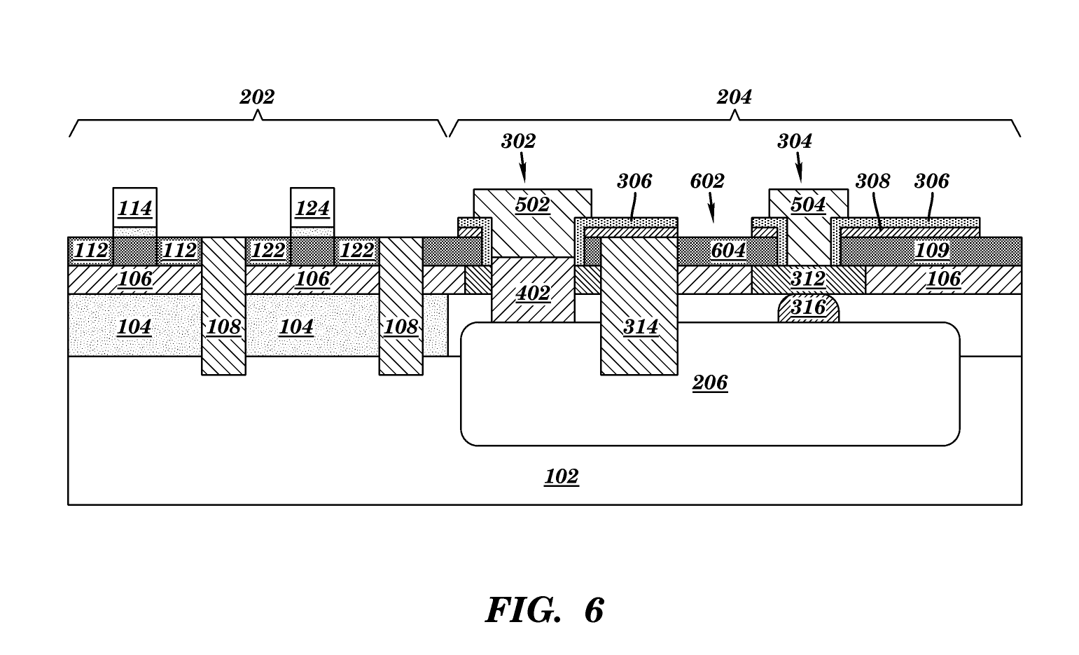

As shown in FIG. 6, a next step may include using an anisotropic (dry) nitride etch to remove a portion of nitride layer 306 and to create an opening 602. Oxide layer 308 may be used as an etch stop. An anisotropic oxide etch or an isotropic wet oxide etch may follow to remove a portion of oxide layer 308 that is exposed in opening 602, using a portion 604 of ETSOI layer 109 as an etch stop. The resulting structure shown in FIG. 7 exposes portion 604 of ETSOI layer 109. Advantageously, a raised extrinsic base layer of BJT may be formed entirely from portion 604 of ETSOI layer 109. It should be noted that the thickness of portion 604 may include the entire thickness of ETSOI layer 109 (from approximately 5 nm to approximately 100 nm, preferably from approximately 6 nm to approximately 8 nm). Advantageously, the structure of disclosed embodiment of the present invention is an improvement over prior art as it eliminates one or more process steps of forming a raised extrinsic base layer, which is typically done by growing a semiconductor layer.

It should be noted that in some embodiments (not shown), a method of BJT fabrication may include, following the creation of opening 602, depositing a layer of metal (such as titanium, or cobalt, or nickel) covering top surface of portion 604 of ETSOI layer 109. The metal layer may be used to form silicided extrinsic base layer for increased conductivity of extrinsic base layer 604. A person skilled in the art may appreciate that the silicidation process includes an annealing process. Still referring to FIG. 6, in various embodiments, an interlevel dielectric (ILD) layer (not shown), preferably comprising borophosphosilicate glass (BPSG), may be deposited over the surface of the BJT structure formed in first region 204. The ILD layer may be deposited using, for example, a CVD process. In various embodiments, the ILD layer is deposited to electrically insulate the BJT structure from a subsequently deposited overlying metal layer.

FIG. 7 illustrates that deep trench isolation regions 702 may next be formed to isolate BJT structure 704 formed in first region 204 from other devices on the same substrate 102, such as FETs 110 and 120 formed in second region 202. Deep trench isolation regions 702 may be formed utilizing a conventional deep trench isolation process well known to those skilled in the art. For example, lithography, etching and filling of the trenches with a trench dielectric, such as silicon oxide, may be used in forming deep trench isolation regions 702. Optionally, a liner may be formed in trenches 702 prior to trench fill, and a densification step may be performed after the trench fill and a planarization process may follow the trench fill as well.

Thus, as described above, the present invention relates to a structure and a method of forming BiCMOS devices on an ETSOI substrate. The BiCMOS devices comprise a plurality of BJTs 704 and CMOS transistors 110 and 120 formed in either adjacent or distant regions 204 and 202 of the ETSOI substrate, respectively. According to an embodiment of the present invention, the structure of BJT 704 comprises buried sub-collector region 206 located within ETSOI substrate 102. The structure of BJT 704 further comprises extrinsic base 604 advantageously formed either entirely or at least partially from a portion of ETSOI layer 109. The structure of BJT 704 further comprises intrinsic base 312 laterally surrounded by BOX layer 106 of the ETSOI substrate. Advantageously, intrinsic base 312 is formed by replacing an etched away portion of BOX layer 106 with a selectively grown layer of epitaxial semiconductor material. The structure of BJT 704 further comprises reach through region 402 which provides a vertical conductive pathway from collector contact region 502 to sub-collector region 206. Advantageously, reach through region 402 may be formed during the same processing step as intrinsic base 312 and subsequently counterdoped by the N-type implanted ions to convert reach through region 402 into heavily doped N-type region. The structure of BJT 704 further comprises emitter 504, which may be formed, advantageously, during the same processing step as formation of collector contact region 502 using a selectively grown layer of epitaxial semiconductor material.

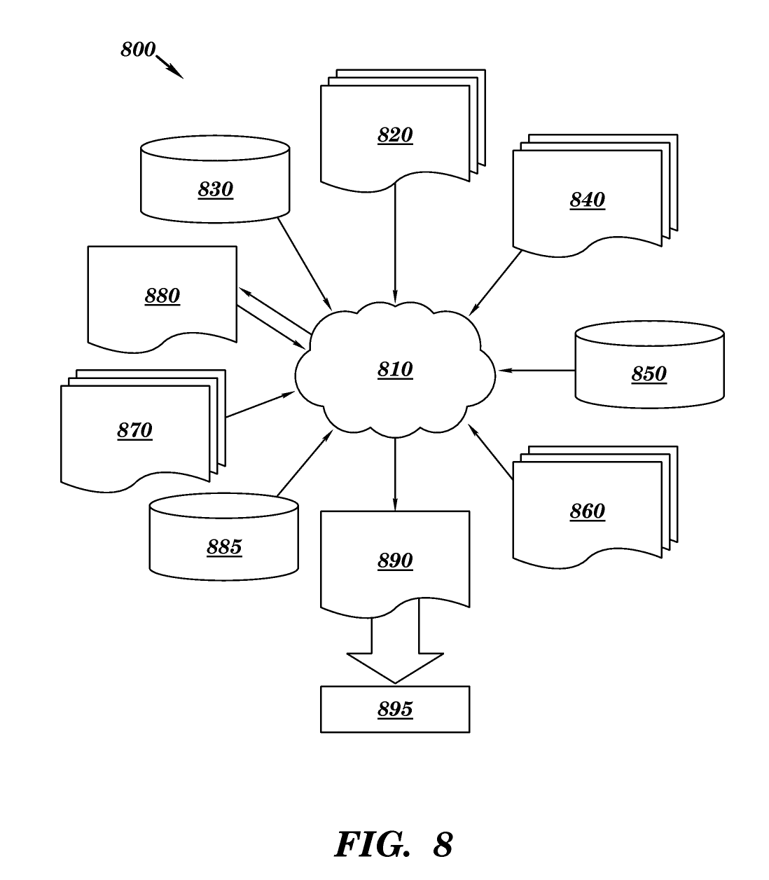

FIG. 8 shows a block diagram of an exemplary design flow 800 used for example, in semiconductor IC logic design, simulation, test, layout, and manufacture. Design flow 800 includes processes, machines and/or mechanisms for processing design structures or devices to generate logically or otherwise functionally equivalent representations of the design structures and/or devices described above and shown in FIGS. 2-7. The design structures processed and/or generated by design flow 800 may be encoded on machine-readable transmission or storage media to include data and/or instructions that when executed or otherwise processed on a data processing system generate a logically, structurally, mechanically, or otherwise functionally equivalent representation of hardware components, circuits, devices, or systems. Machines include, but are not limited to, any machine used in an IC design process, such as designing, manufacturing, or simulating a circuit, component, device, or system. For example, machines may include: lithography machines, machines and/or equipment for generating masks (e.g., e-beam writers), computers or equipment for simulating design structures, any apparatus used in the manufacturing or test process, or any machines for programming functionally equivalent representations of the design structures into any medium (e.g., a machine for programming a programmable gate array).

Design flow 800 may vary depending on the type of representation being designed. For example, a design flow 800 for building an application specific IC (ASIC) may differ from a design flow 800 for designing a standard component or from a design flow 800 for instantiating the design into a programmable array, for example a programmable gate array (PGA) or a field programmable gate array (FPGA) offered by Altera® Inc. or Xilinx® Inc.

FIG. 8 illustrates multiple such design structures including an input design structure 820 that is preferably processed by a design process 810. Design structure 820 may be a logical simulation design structure generated and processed by design process 810 to produce a logically equivalent functional representation of a hardware device. Design structure 820 may also or alternatively comprise data and/or program instructions that when processed by design process 810, generate a functional representation of the physical structure of a hardware device. Whether representing functional and/or structural design features, design structure 820 may be generated using electronic computer-aided design (ECAD) such as implemented by a core developer/designer. When encoded on a machine-readable data transmission, gate array, or storage medium, design structure 820 may be accessed and processed by one or more hardware and/or software modules within design process 810 to simulate or otherwise functionally represent an electronic component, circuit, electronic or logic module, apparatus, device, or system such as those shown in FIGS. 2-7. As such, design structure 820 may comprise files or other data structures including human and/or machine-readable source code, compiled structures, and computer-executable code structures that when processed by a design or simulation data processing system, functionally simulate or otherwise represent circuits or other levels of hardware logic design. Such data structures may include hardware-description language (HDL) design entities or other data structures conforming to and/or compatible with lower-level HDL design languages such as Verilog and VHDL, and/or higher level design languages such as C or C++.

Design process 810 preferably employs and incorporates hardware and/or software modules for synthesizing, translating, or otherwise processing a design/simulation functional equivalent of the components, circuits, devices, or logic structures shown in FIGS. 2-7 to generate a netlist 880 which may contain design structures such as design structure 820. Netlist 880 may comprise, for example, compiled or otherwise processed data structures representing a list of wires, discrete components, logic gates, control circuits, I/O devices, models, etc. that describes the connections to other elements and circuits in an integrated circuit design. Netlist 880 may be synthesized using an iterative process in which netlist 880 is resynthesized one or more times depending on design specifications and parameters for the device. As with other design structure types described herein, netlist 880 may be recorded on a machine-readable data storage medium or programmed into a programmable gate array. The medium may be a non-volatile storage medium such as a magnetic or optical disk drive, a programmable gate array, a compact flash, or other flash memory. Additionally, or in the alternative, the medium may be a system or cache memory, buffer space, or electrically or optically conductive devices and materials on which data packets may be transmitted and intermediately stored via the Internet, or other networking suitable means.

Design process 810 may include hardware and software modules for processing a variety of input data structure types including netlist 880. Such data structure types may reside, for example, within library elements 830 and include a set of commonly used elements, circuits, and devices, including models, layouts, and symbolic representations, for a given manufacturing technology (e.g., different technology nodes, 32 nm, 45 nm, 90 nm, etc.). The data structure types may further include design specifications 840, characterization data 850, verification data 860, design rules 870, and test data files 885 which may include input test patterns, output test results, and other testing information. Design process 810 may further include, for example, standard mechanical design processes such as stress analysis, thermal analysis, mechanical event simulation, process simulation for operations such as casting, molding, and die press forming, etc. One of ordinary skill in the art of mechanical design can appreciate the extent of possible mechanical design tools and applications used in design process 810 without deviating from the scope and spirit of the invention. Design process 810 may also include modules for performing standard circuit design processes such as timing analysis, verification, design rule checking, place and route operations, etc.

Design process 810 employs and incorporates logic and physical design tools such as HDL compilers and simulation model build tools to process design structure 820 together with some or all of the depicted supporting data structures along with any additional mechanical design or data (if applicable), to generate a second design structure 890. Design structure 890 resides on a storage medium or programmable gate array in a data format used for the exchange of data of mechanical devices and structures (e.g., information stored in a IGES, DXF, Parasolid XT, JT, DRG, or any other suitable format for storing or rendering such mechanical design structures). Similar to design structure 820, design structure 890 preferably comprises one or more files, data structures, or other computer-encoded data or instructions that reside on transmission or data storage media and that when processed by an ECAD system generate a logically or otherwise functionally equivalent form of one or more of the embodiments of the invention shown in FIGS. 2-7. In an embodiment, design structure 890 may comprise a compiled, executable HDL simulation model that functionally simulates the devices shown in FIGS. 2-7.

Design structure 890 may also employ a data format used for the exchange of layout data of integrated circuits and/or symbolic data format (e.g., information stored in a GDSII (GDS2), GL1, OASIS, map files, or any other suitable format for storing such design data structures). Design structure 890 may comprise information such as, for example, symbolic data, map files, test data files, design content files, manufacturing data, layout parameters, wires, levels of metal, vias, shapes, data for routing through the manufacturing line, and any other data required by a manufacturer or other designer/developer to produce a device or structure as described above and shown in FIGS. 2-7. Design structure 890 may then proceed to a stage 895 where, for example, design structure 890 proceeds to tape-out, is released to manufacturing, is released to a mask house, is sent to another design house, is sent back to the customer, etc.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising”, when used in this specification, specify the presence of stated features, integers, steps, operations, elements, and/or components, but do not preclude the presence or addition of one or more other features, integers, steps, operations, elements, components, and/or groups thereof.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor device structure comprising:
a substrate having a layer of semiconductor material upon an insulating layer; and
a bipolar junction transistor structure formed in a first region of the substrate having an extrinsic base layer formed at least partially from a portion of the layer of semiconductor material.

2. The semiconductor device structure of claim 1, wherein the extrinsic base layer is formed entirely from a portion of the layer of semiconductor material.

3. The semiconductor device structure of claim 1, wherein the layer of semiconductor material has a thickness ranging from approximately 5 nm to approximately 100 nm and wherein the insulating layer comprises a buried oxide layer having a thickness ranging from approximately 10 nm to approximately 200 nm.

4. The semiconductor device structure of claim 1, further comprising a field effect transistor (FET) structure formed in a second region of the substrate.

5. The semiconductor device structure of claim 4, wherein the FET structure comprises:
a channel formed in the layer of semiconductor material;
a source formed in the layer of semiconductor material, wherein the source includes a lightly doped source region adjacent to the channel;
a drain formed in the layer of semiconductor material, wherein the drain includes a lightly doped drain region adjacent to the channel; and
a gate formed upon the layer of semiconductor material.

6. The semiconductor device structure of claim 1, wherein the bipolar junction transistor structure comprises an intrinsic base layer laterally surrounded by the insulating layer.

7. The semiconductor device structure of claim 1, wherein the bipolar junction transistor structure comprises a reach-through region, the reach-through region electrically connecting a collector contact region with a buried sub-collector layer.

8. The semiconductor device structure of claim 7, wherein the bipolar junction transistor structure further comprises an emitter layer, the emitter layer and the collector contact region comprising epitaxially-grown material, the emitter layer and the collector contact region formed at least partially over the layer of semiconductor material.

9. The semiconductor device structure of claim 4, wherein the first region is substantially adjacent to the second region.

10. A method of forming a semiconductor device structure comprising:
providing a substrate having a layer of semiconductor material that is present on an insulating layer; and
forming a bipolar junction transistor structure in a first region of the substrate, wherein forming the bipolar junction transistor structure comprises forming an extrinsic base layer at least partially from a portion of the layer of semiconductor material.

11. The method of claim 10, wherein forming the bipolar junction transistor structure comprises forming the extrinsic base layer entirely from the portion of the layer of semiconductor material.

12. The method of claim 10, wherein the layer of semiconductor material has a thickness ranging from approximately 5 nm to approximately 100 nm and wherein the insulating layer comprises a buried oxide layer having a thickness ranging from approximately 10 nm to approximately 200 nm.

13. The method of claim 10, wherein the bipolar junction transistor structure comprises an npn transistor structure.

14. The method of claim 10, further comprising forming a field effect transistor (FET) structure in a second region of the substrate.

15. The method of claim 14, wherein forming the FET structure comprises:
forming a channel in the layer of semiconductor material;
forming a source in the layer of semiconductor material, wherein the source includes a lightly doped source region adjacent to the channel;
forming a drain in the layer of semiconductor material, wherein the drain includes a lightly doped drain region adjacent to the channel; and
forming a gate, wherein the gate overlays the layer of semiconductor material.

16. The method of claim 10, wherein forming the bipolar junction transistor structure further comprises forming an intrinsic base layer, wherein the intrinsic base layer is laterally surrounded by the insulating layer.

17. The method of claim 10, wherein forming the bipolar junction transistor structure further comprises:
forming a buried sub-collector layer;
forming a collector contact region by selective epitaxy, wherein the collector contact region extends at least partially over the layer of semiconductor material; and
forming a reach-through region, wherein the reach-through region electrically connects the collector contact region with the buried sub-collector layer.

18. The method of claim 10, wherein forming the bipolar junction transistor structure further comprises forming an emitter layer by selective epitaxy and wherein the emitter layer extends at least partially over the layer of semiconductor material.

19. The method of claim 14, wherein the first region is formed substantially adjacent to the second region.

20. A design structure tangibly embodied in a machine readable medium for designing, manufacturing, or testing an integrated circuit, the design structure comprising:
a substrate having a layer of semiconductor material upon an insulating layer; and
a bipolar junction transistor structure formed in a first region of the substrate having an extrinsic base layer formed at least partially from a portion of the layer of semiconductor material.
